(19) United States
(12) Patent Application Publication
(10) Pub. No.: US 2026/0082858 A1
(43) Pub. Date: Mar. 19, 2026

(54) SEMICONDUCTOR MANUFACTURING TOOL

(71) Applicant: Kioxia Corporation, Tokyo (JP)

(72) Inventor: Hiroyuki ODE, Yokkaichi Mie (JP)

(21) Appl. No.: 19/079,216

(22) Filed: Mar. 13, 2025

(30) Foreign Application Priority Data
Sep. 18, 2024 (JP) 2024-161476

(51) Int. Cl. H01L 21/677; H01L 21/321; H01L 21/67; H01L 21/768

(52) U.S. Cl. CPC H10P 72/3412; H10P 52/203; H10P 72/0404; H10P 72/0444; H10W 20/065

(57) ABSTRACT

According to one embodiment, there is provided a semiconductor manufacturing tool that is capable of further facilitating an electrochemical process. The semiconductor manufacturing tool according to the embodiment includes a plurality of process baths, an anode and a cathode, and an electrical circuit. Each of the plurality of process baths is capable of containing a substrate processing liquid and a first substrate. The anode and the cathode are provided for each of the process baths. The electrical circuit electrically connects a plurality of first substrates held in the substrate processing liquid via the anode and the cathode and supplies electrical power via the anode and the cathode for subjecting the plurality of first substrates to an electrochemical process.

### CROSS-REFERENCE TO RELATED APPLICATION(S)

This application is based upon and claims the benefit of priority from Japanese Patent Application No. 2024-161476, filed Sep. 18, 2024, the entire contents of which are incorporated herein by reference.

### FIELD

Embodiments described herein relate generally to a semiconductor manufacturing tool.

### BACKGROUND

In an anodizer for subjecting a substrate (e.g., silicon wafer) to an anodization process, it is necessary to hold the silicon wafer in a chemical bath in a liquid-tight state, and it may in some cases be necessary to secure the silicon wafer in a tightly sealed manner by using an O-ring or the like. In this case, automated introduction of silicon wafers into the anodizer is difficult, making it challenging to develop a manufacturing tool intended for mass production (for example, batch processing tool).

### BRIEF DESCRIPTION OF THE DRAWINGS

FIG. 1 is a diagram illustrating the structure of a semiconductor manufacturing tool of a first embodiment.

FIG. 2 is a sectional view illustrating the structure of a substrate processor of the first embodiment.

FIG. 3 is another sectional view illustrating the structure of the substrate processor of the first embodiment.

FIG. 4 is an enlarged sectional view illustrating the structure of the substrate processor of the first embodiment.

FIG. 5 is a diagram illustrating the structure of an electrode of a modification of the first embodiment.

FIG. 6 is an enlarged sectional view illustrating the structure of the substrate processor of the first embodiment.

FIG. 7 is a perspective view illustrating the structure of a substrate holder of the first embodiment.

FIG. 8 is a sectional view illustrating the structure of the substrate holder of the first embodiment.

FIGS. 9A-9C are sectional views illustrating substrates in motion while being held by the substrate holder of the first embodiment.

FIG. 10 is an enlarged sectional view illustrating the structure of a substrate processor of a second embodiment.

FIG. 11 is a sectional view illustrating the structure of a substrate processor of a third embodiment.

FIG. 12 is a sectional view illustrating the structure of a semiconductor device of a fourth embodiment.

FIG. 13 is an enlarged sectional view illustrating the structure of the semiconductor device of the fourth embodiment.

FIGS. 14A-14C, and 15A-15C are sectional views illustrating a manufacturing method of the semiconductor device of the fourth embodiment.

FIGS. 16A-16B, 17A-17B, 18A-18B, 19A-19B, and 20A-20B are sectional views illustrating details of the manufacturing method of the semiconductor device of the fourth embodiment.

FIG. 21 is a sectional view illustrating the structure of a semiconductor device of a modification of the fourth embodiment.

### DETAILED DESCRIPTION

Embodiments provide a semiconductor manufacturing tool that is capable of further facilitating an electrochemical process.

In general, according to one embodiment, a semiconductor manufacturing tool includes a plurality of process baths, an anode and a cathode, and an electrical circuit. Each of the plurality of process baths is capable of containing a substrate processing liquid and accommodating a first substrate. The anode and the cathode are provided for each of the process baths. The electrical circuit electrically connects a plurality of first substrates placed in the substrate processing liquid, via the anode and the cathode, and supplies electrical power via the anode and the cathode for subjecting the plurality of first substrates to an electrochemical process.

Embodiments according to the present invention will now be described with reference to drawings. The embodiments are not intended to limit the scope of the present invention. The drawings are schematic and conceptual, and proportions or the like of any part are not necessarily the same as actual ones. In the specification and drawings, elements that are similar to those described previously with respect to any already-described drawing are given like reference signs and detailed description will not be repeated as appropriate.

### First Embodiment

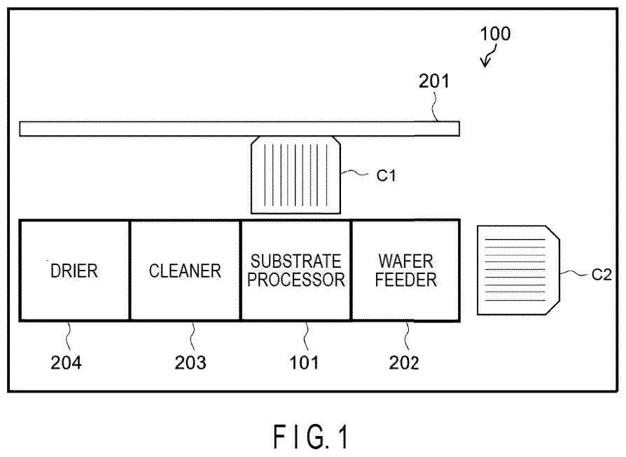

FIG. 1 is a diagram illustrating the structure of a semiconductor manufacturing tool 100 of the first embodiment.

The semiconductor manufacturing tool 100 includes a transfer apparatus 201, a wafer feeder 202 (also referred to as a wafer loader), a substrate processor 101, a cleaner 203, and a drier 204.

The transfer apparatus 201 transfers a carrier C1 to and from the wafer feeder 202, the substrate processor 101, the cleaner 203, and the drier 204. The carrier C1 is capable of accommodating a plurality of substrates W.

The wafer feeder 202 feeds the plurality of substrates W accommodated in the carrier C1 to another transfer carrier C2.

The substrate processor 101 processes the plurality of substrates W. The substrate processor 101 is a batch processing tool.

The cleaner 203 cleans the plurality of substrates W processed by the substrate processor 101. The cleaner 203 performs a rinsing process.

The drier 204 dries the plurality of substrates W cleaned by the cleaner 203.

Next, the substrate processor 101 will be described in detail.

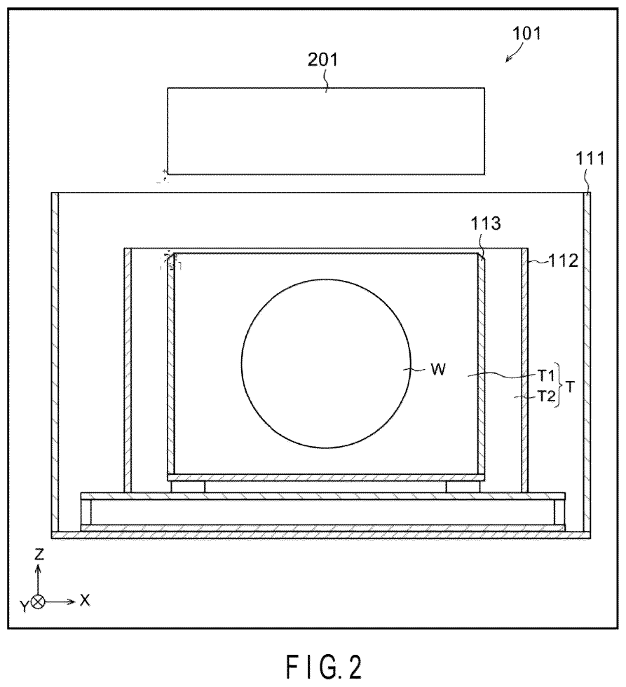

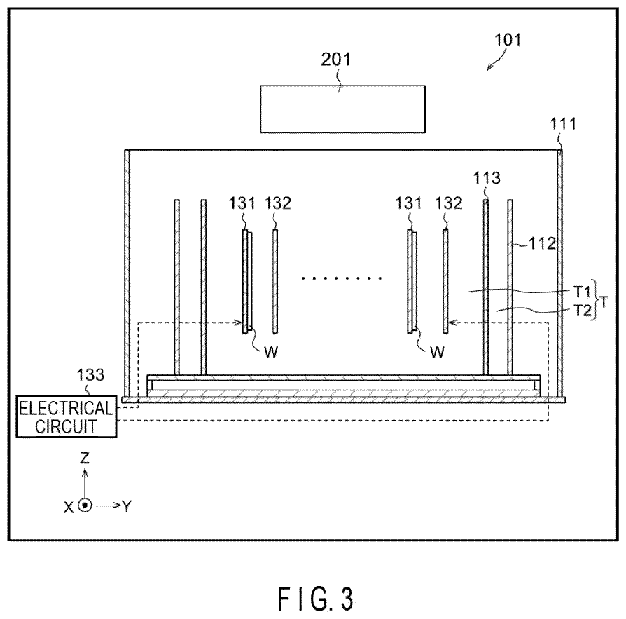

FIGS. 2 and 3 are sectional views illustrating the structure of the substrate processor 101 of the first embodiment.

The substrate processor 101 is an apparatus for processing the substrate W and is, for example, an anodizer that forms a porous layer on a surface of the substrate W by anodization. FIGS. 2 and 3 illustrate different vertical sections of the substrate processor 101.

FIGS. 2 and 3 indicate the X-direction, the Y-direction, and the Z-direction, which are perpendicular to each other. In the specification, the +Z-direction is treated as an upward direction, and the −Z-direction is treated as a downward direction. Furthermore, the direction that is parallel to the Z-direction is treated as the up-down direction, and the direction that is perpendicular to the Z-direction is treated as the horizontal direction. The −Z-direction may coincide with the direction of gravity or may not coincide with the direction of gravity.

The substrate processor 101 includes an outer container 111, an inner container 112, a partition wall 113, an electrode 131, an electrode 132, and an electrical circuit 133.

As illustrated in FIGS. 2 and 3, the inner container 112 is disposed in the outer container 111, and the partition wall 113 is arranged in the inner container 112. As a result, in the inner container 112, a reservoir T is formed, which includes an inner bath T1 surrounded by the partition walls 113 and an outer bath T2 between the partition wall 113 and the inner container 112. The reservoir T stores an electrolyte solution. The electrolyte solution is supplied from a weighing tank, which is not illustrated, to the inner bath T1, and the electrolyte solution that overflows over the partition wall 113 from the inner bath T1 is collected in the outer bath T2. The inner bath T1 is capable of accommodating a plurality of substrates W. The planar shape of each of the substrates W is, for example, circular or quadrangular. The planar shape of the substrate W illustrated in FIG. 2 is circular. The reservoir T, the electrolyte solution, and the substrate W are examples of the process bath, the substrate processing liquid, and the first substrate, respectively. The substrate W is, for example, a semiconductor wafer such as an Si (silicon) wafer.

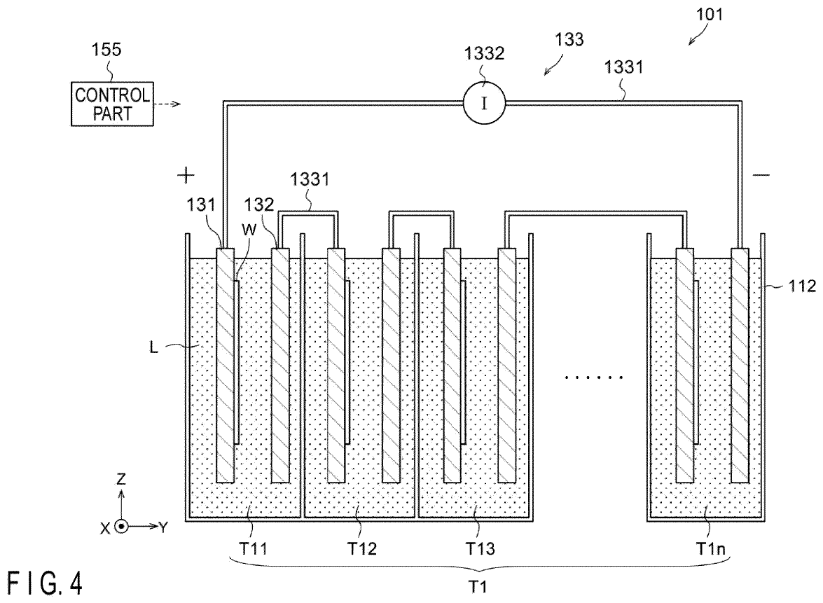

A plurality of electrodes 131 and a plurality of electrodes 132 are provided. The substrate W illustrated in FIG. 3 is disposed between the electrode 131 and the electrode 132. The electrodes 131 and 132, the substrate W, and peripheral configurations thereof will be described in detail later with reference to FIG. 4.

In the example illustrated in FIG. 3, the electrodes 131 and 132 are disposed in the inner bath T1 and used to electrically process each substrate W. Each substrate W is held in the inner bath T1 between the electrode 131 and the electrode 132. The electrodes 131 and 132 are capable of processing a plurality of substrates W at the same time (batch processing). For example, in a case in which the electrode 131 is an anode and the electrode 132 is a cathode, a porous layer can be formed by anodization on each surface of each substrate W on the side of the electrode 132. The surface of each substrate W on the side of the electrode 132 is an example of a first surface, and the surface of each substrate W on the side of the electrode 131 is an example of a second surface. Each substrate W is held by a substrate holder 162 such that the former surface faces on the side of the electrode 132 and the latter surface faces on the side of the electrode 131.

The electrical circuit 133 supplies electrical power to the electrode 131 and the electrode 132. The electrical circuit 133 will be described in detail later with reference to FIG. 4.

FIG. 4 is an enlarged sectional view illustrating the structure of the substrate processor 101 of the first embodiment.

FIG. 4 illustrates the inner container 112, the electrode 131, the electrode 132, the electrical circuit 133, and the reservoir T (e.g., inner bath T1), which are described above. The substrate processor 101 further includes a control part 155 as illustrated in FIG. 4.

FIG. 4 further illustrates an electrolytic solution L contained in the inner bath T1. The electrolytic solution L corresponds to the electrolyte solution described above. The electrolytic solution L is, for example, an HF (hydrogen fluoride) aqueous solution.

In FIG. 4, the electrode 131 is the anode and the electrode 132 is the cathode, and a porous layer is formed by anodization on the surface of each substrate W on the side of the electrode 132. The porous layer is formed, for example, by generating porosity in a material layer formed in advance on the surface of each substrate W on the side of the electrode 132. In a case in which the material layer is a polysilicon layer (which is a semiconductor layer), the porous layer is a porous polysilicon layer (and thus, a porous semiconductor layer). The material layer is an example of a first layer. Meanwhile, the porous layer may be formed within each substrate W, for example, by generating porosity in a part of each substrate W near the surface of each substrate W on the side of the electrode 132.

The control part 155 is a control circuit that controls various operations of the substrate processor 101. For example, the control part 155 controls an operation of the electrical circuit 133 or the like to perform anodization.

The inner bath T1 includes a plurality of inner baths T11 to T1n (n is a natural number not less than 2). The number of inner baths T11 to T1n is, but not limited to, 25, for example.

Each of the inner baths T11 to T1n is capable of containing the electrolytic solution L and accommodating the substrate W.

The electrodes 131 and 132 are provided for each of the inner baths T11 to T1n. That is, a pair of electrodes 131 and 132 is provided for each of the inner baths T11 to T1n.

The substrate W illustrated in FIG. 4 is secured to the electrode 131.

The electrical circuit 133 includes a connecting circuit 1331 and a power supply part 1332.

The connecting circuit 1331 electrically connects a plurality of substrates W (inner baths T11 to T1n) held in the electrolytic solution L via the electrodes 131 and 132. The connecting circuit 1331 illustrated in FIG. 4 connects the plurality of substrates W (inner baths T11 to T1n) in the electrolytic solution L in series via the electrodes 131 and 132. For example, the connecting circuit 1331 may be provided on each of the electrodes 131 so that when the electrodes 131 and the substrates W are submerged in the inner baths T11 to T1n, the connecting circuit 1331 provided on each of the electrodes 131 that are submerged in inner baths T12 to T1n contacts the electrode 132 that is submerged in a neighboring inner bath to be electrically connected thereto.

The power supply part 1332 is a power supply circuit that energizes the electrodes 131 and 132, that is, supplies electrical power via the electrodes 131 and 132 for subjecting the plurality of substrates W to the anodization process. The power supply part 1332 is, for example, an electrical current source. The power supply part 1332 supplies electrical power via the electrodes 131 and 132 through current control, which includes controlling current flowing through the plurality of substrates W. The current control allows current to flow evenly through all the substrates W.

Next, the structure of the electrode 131 will be described in detail.

The planar shape of the electrode 131 is the same as, for example, the planar shape of the substrate W. For example, the planar shape of the electrode 131 is circular.

The requirement for the material of the electrode 131 is that, for example, it is insoluble in an HF solution, unoxidized at an Si anodic oxidation potential (−1.2V vs NHE (normal hydrogen electrode, also called standard hydrogen electrode), irreducible at a hydrogen generation potential (0V vs NHE), and less reducible than oxygen.

The electrode 131 includes, for example, a base metal that is less susceptible to oxidation (with a higher standard potential) than the material of the substrate W (which is, for example, Si), a compound semiconductor that is less susceptible to oxidation than the material of the substrate W, carbon, or a conductive polymer. Such a base metal that is less susceptible to oxidation than the material of the substrate W includes, for example, tungsten (W), molybdenum (Mo), cobalt (Co), copper (Cu), Zinc (Zn), or the like. A compound semiconductor that is less susceptible to oxidation than the material of the substrate W includes, for example, indium-tin-oxide (InTiO) or indium-gallium-zinc-oxide (IGZO).

Such a conductive polymer includes, for example, polyacetylene, poly-(p-phenylene vinylene), polypyrrole, polythiophene, polyaniline, poly-(p-phenylene sulfide), or the like.

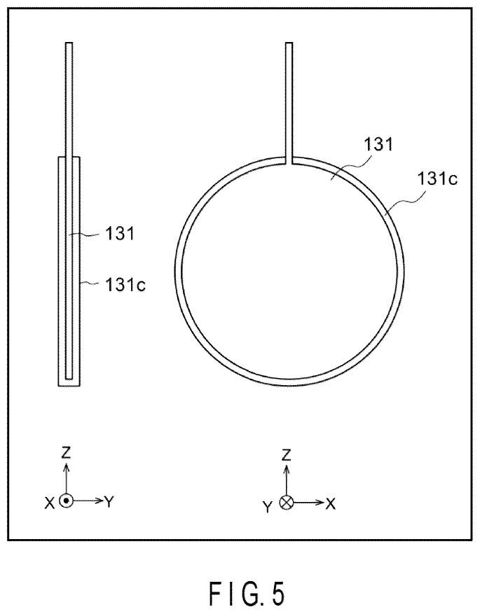

FIG. 5 is a diagram illustrating the structure of the electrode 131 of a modification of the first embodiment. The modification of the first embodiment is different from the first embodiment in that it is provided with a covering film 131c.

The electrode 131 includes the covering film 131c (also referred to as a “coating film”) that covers at least a partial region of the electrode 131. The covering film 131c has electrical conductivity. The covering film 131c includes a material different from the material of the electrode 131. The covering film 131c is provided in a region on a surface of the electrode 131 that is in direct contact with the substrate W. In this way, the covering film 131c can prevent the electrode 131 from being in direct contact with the substrate W, so that it is possible to prevent the substrate W from being contaminated due to the material of the electrode 131.

The requirement for the material of the covering film 131c is that, for example, it is insoluble in an HF solution and unoxidized at an Si anodic oxidation potential (−1.2V vs NHE).

The electrode 131 includes, for example, a noble metal such as platinum (Pt). The covering film 131c includes, for example, a conductive polymer. Note that in a case in which the covering film 131c includes a conductive polymer, the electrode 131 is not limited to a noble metal and may include any conductive material described above excluding the conductive polymer.

Next, how the substrate W is held will be described in detail.

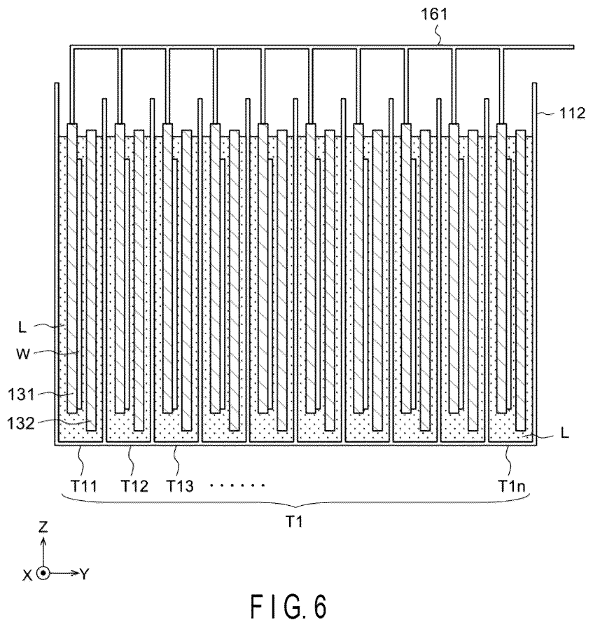

FIG. 6 is an enlarged sectional view illustrating the structure of the substrate processor 101 of the first embodiment.

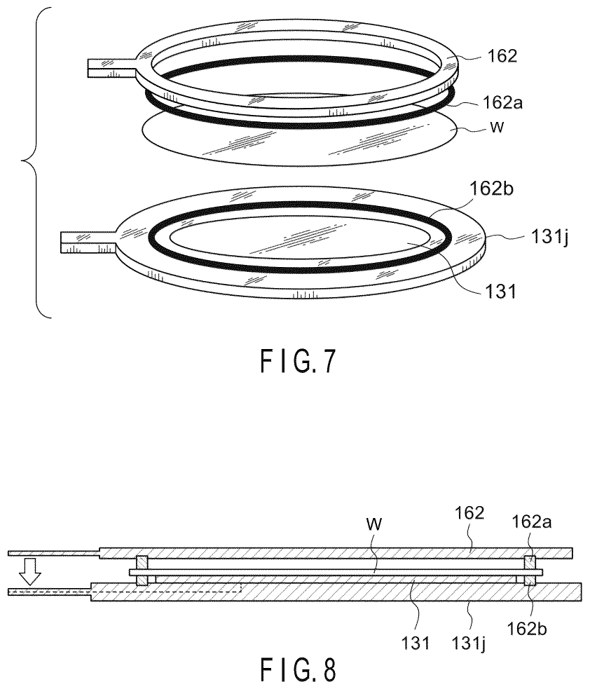

The substrate processor 101 further includes an electrode holder 161 and a substrate holder 162. Note that the substrate holder 162 is illustrated in FIG. 7 and is not illustrated in FIG. 6.

The electrode holder 161 holds a plurality of electrodes 131. The electrode holder 161 also holds the electrodes 131 such that the electrodes 131 with the substrates W being held thereon are allowed to be brought into and out of the electrolytic solution L.

The substrate holder 162 is capable of holding the substrate W in a way to secure the substrate W to the electrode 131.

The plurality of electrodes 132 are each fixed to each of the inner baths T11 to T1n.

FIG. 7 is a perspective view illustrating the structure of the substrate holder 162 of the first embodiment. FIG. 8 is a sectional view illustrating the structure of the substrate holder 162 of the first embodiment.

The substrate processor 101 further includes a jig 131j. The jig 131j holds the electrode 131. The jig 131j illustrated in FIG. 7 holds an outer circumferential portion of the electrode 131. Furthermore, the electrode 131 illustrated in FIG. 8 is in contact with the second surface of the substrate W.

The substrate holder 162 is capable of holding the substrate W to expose the first surface of the substrate W to the electrolytic solution L. The portion of the substrate holder 162 that secures the substrate W has, for example, a ring shape. The substrate holder 162 and the electrode 131 are provided such that the outer circumferential portion of the substrate W is clamped therebetween.

O-rings 162a and 162b are also provided. The O-ring 162a is provided between the substrate holder 162 and the substrate W. The O-ring 162b is provided between the substrate W and the electrode 131 (jig 131j). The electrolytic solution L is prevented by the O-ring 162b from entering the side of the second surface of the substrate W.

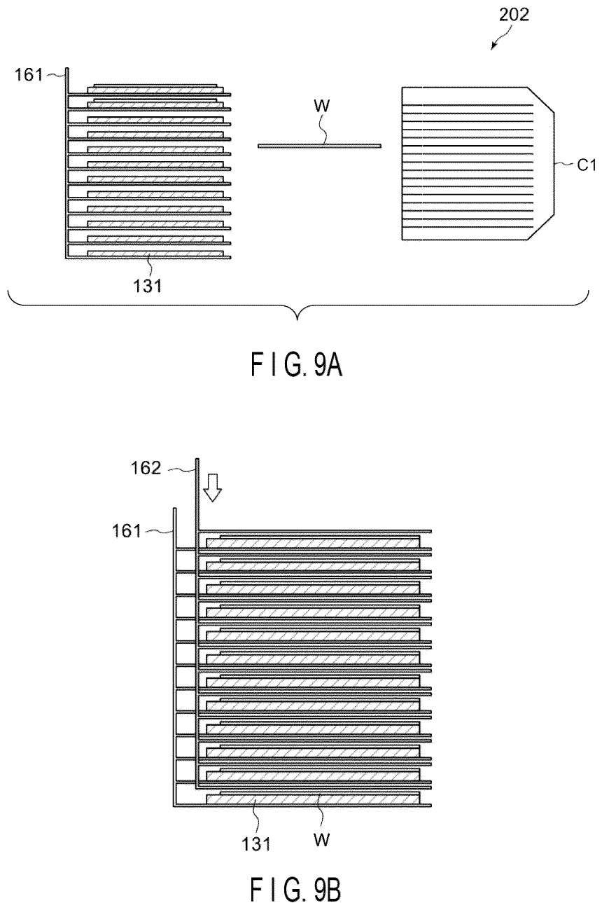

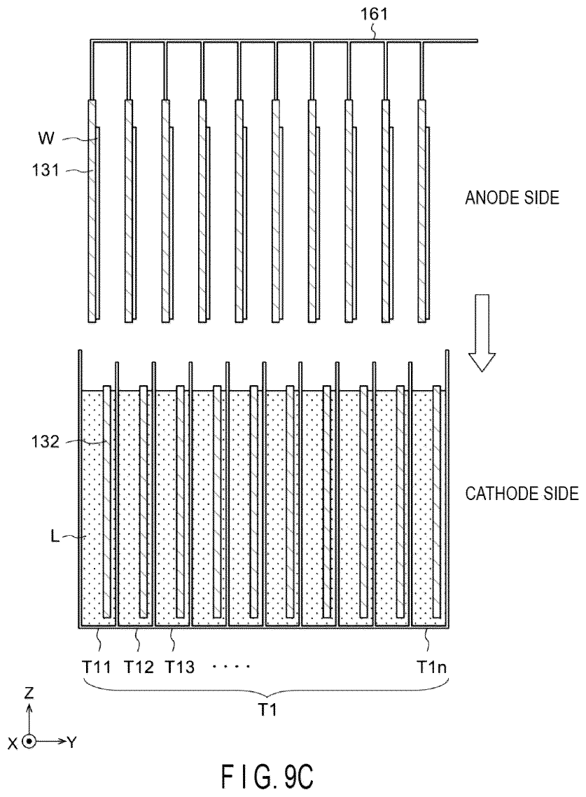

FIGS. 9A to 9C are sectional views illustrating substrates W in motion while being held by the substrate holder 162 of the first embodiment.

First, as illustrated in FIG. 9A, the wafer feeder 202 feeds the substrates W accommodated in the carrier C1 onto the electrodes 131.

Next, as illustrated in FIG. 9B, the substrate holder 162 secures each of the plurality of substrates W to each of the plurality of electrodes 131 in a close contact manner.

Next, as illustrated in FIG. 9C, the transfer apparatus 201 brings the electrode 131 and the substrate W into the electrolytic solution L. The electrode holder 161 holds the plurality of electrodes 131 such that the plurality of electrodes 131 are each allowed to be brought into and out of the electrolytic solution L in each of the inner baths T11 to T1n. Note that the substrate holder 162 is not illustrated in FIG. 9C.

As illustrated in FIGS. 9A to 9C, the plurality of substrates W are secured to the plurality of electrodes 131 by the substrate holder 162 and brought into the electrolytic solution L. In this way, it is not necessary to secure the substrates W to be subjected to the anodization process in a liquid-tight state. As a result, automated introduction of the plurality of substrates W into substrate processor 101 can further be facilitated. Furthermore, the electrode holder 161 and the substrate holder 162 make it easier to process the plurality of substrates W at the same time (e.g., in a batch processing).

As described above, according to the first embodiment, each of the plurality of inner baths T11 to T1n is capable of containing the electrolytic solution L and accommodating the substrate W. The connecting circuit 1331 electrically connects the plurality of substrates W held in the electrolytic solution L via the electrodes 131 and 132. The power supply part 1332 supplies electrical power via the electrodes 131 and 132 for subjecting the plurality of substrates W to the anodization process. In this way, it is possible to subject the plurality of substrates W to the anodization process at the same time (e.g., in a batch processing) and form a porous layer on a surface of the substrate W on a batch basis. Accordingly, the anodization process can further be facilitated.

Note that the anodization process is not a limitation, and the first embodiment may be used for any other electrochemical processes. In such other electrochemical processes, the electrode 132 and the substrate W may be secured to each other and allowed to be brought into and out of the electrolytic solution L.

As described with reference to FIGS. 9A to 9C, it is possible to facilitate automated introduction of the plurality of substrates W into the substrate processor 101. Furthermore, the electrode holder 161 and the substrate holder 162 make it easier to process the plurality of substrates W at the same time (e.g., in a batch processing).

Although the substrate holder 162 illustrated in FIGS. 7 and 8 is a mechanical holding mechanism, it may be a vacuum chuck.

In addition, additives such as a surfactant or alcohol (e.g., IPA) may be added to the electrolytic solution L.

### Second Embodiment

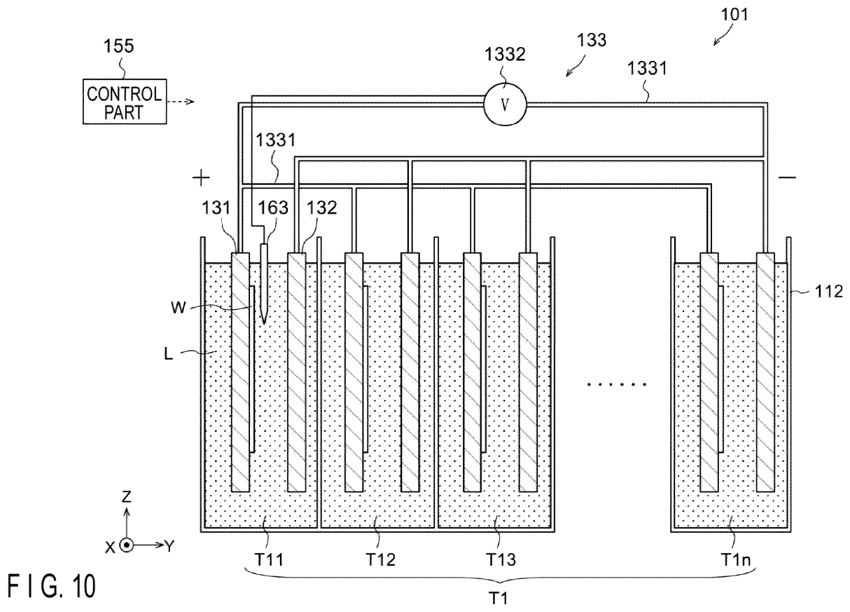

FIG. 10 is an enlarged sectional view illustrating the structure of the substrate processor 101 of the second embodiment. The second embodiment is different from the first embodiment in that the plurality of substrates W are connected in parallel.

The connecting circuit 1331 connects the plurality of substrates W (accommodated in inner baths T11 to T1n) in the electrolytic solution L in parallel via the electrodes 131 and 132.

The substrate processor 101 further includes a reference electrode 163. The reference electrode 163 is provided in one of the inner baths T11 to T1n. The reference electrode 163 is, for example, a hydrogen electrode, an Ag/AgCl electrode, or the like.

The power supply part 1332 is, for example, a voltage source. Based on a detection result of the reference electrode 163, the power supply part 1332 supplies electrical power via the electrode 131 and the electrode 132 through a voltage control for controlling voltage applied to the plurality of substrates W. For example, the power supply part 1332 controls a potential of the electrode 131, which is a working electrode, by means of the reference electrode.

Comparing to the first embodiment, in the second embodiment, the plurality of substrates W are connected in parallel. In this way, voltage can be supplied to the electrodes 131 and 132 through the voltage control. In the case of the series connection and the current control, the voltage applied to each substrate W is not necessarily equal depending on the conditions of each substrate W. In contrast, in the second embodiment, the voltage applied to each substrate W (accommodated in each of the inner baths T11 to T1n) can further be equalized, so that the anodization of each substrate W can be achieved more evenly. As a result, it is possible to prevent variation among the substrates W in batch processing.

In addition, in the second embodiment, it is possible to apply any voltage to each substrate W at which anodic oxidation in Si occurs.

In addition, in the second embodiment, it is possible to prevent the total applied voltage from growing even with a large number of substrates to be processed. In the case of the series connection and the current control, the larger the number of substrates W to be processed is, the total applied voltage grows. In contrast, in the second embodiment, all substrates W1 (accommodated in inner baths T11 to T1n) can be supplied with the same voltage. Accordingly, when there is a larger number of substrates W is to be processed, the parallel connection and the voltage control are preferable.

As in the second embodiment, the plurality of substrates W may be connected in parallel. With the semiconductor manufacturing tool 100 according to the second embodiment, it is possible to produce similar effects as in the first embodiment.

### Third Embodiment

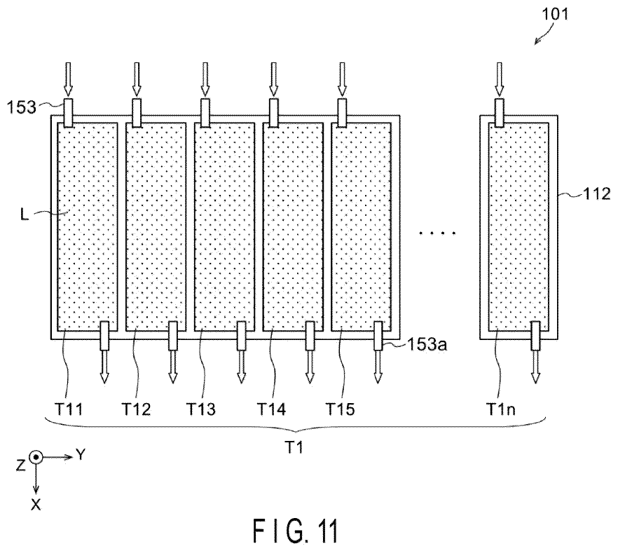

FIG. 11 is a sectional view illustrating the structure of the substrate processor 101 of the third embodiment. The third embodiment is different from the first embodiment in that the electrolytic solution L in the inner baths T11 to T1n is circulated.

The substrate processor 101 further includes an electrolytic solution supply part 153 and an electrolytic solution drain part 153a. The electrolytic solution supply part 153 and the electrolytic solution drain part 153a are provided for each of the inner baths T11 to T1n.

The electrolytic solution supply part 153 supplies the electrolytic solution L into the inner baths T11 to T1n. The electrolytic solution supply part 153 of the embodiment resupplies the electrolytic solution L drained from the inner baths T11 to T1n into the reservoir T to cause the electrolytic solution L to circulate in the substrate processor 101.

The electrolytic solution drain part 153a drains the electrolytic solution L from the inner baths T11 to T1n. The electrolytic solution drain part 153a drains the electrolytic solution L as a waste liquid that includes reaction by-products (for example, SiFhd 6²⁻) of the anodization process. The accumulation of reaction by-products in the inner baths T11 to T1n may disturb the chemical equilibrium, so that desired reactions may be less likely to occur. It is possible to prevent the reaction efficiency from degrading by draining such reaction by-products.

Accordingly, the electrolytic solution supply part 153 and the electrolytic solution drain part 153a as circulation paths cause the electrolytic solution L in the inner baths T11 to T1n to circulate at a substantially constant flow rate during an anodization process to maintain a substantially constant concentration of the electrolytic solution L (chemical liquid) (HF and surfactant) near the substrate W.

The substrate processor 101 may further include a temperature controlling part. The temperature controlling part controls the temperature of the electrolytic solution L supplied by the electrolytic solution supply part 153. For example, when the temperature of the electrolytic solution L in the inner baths T11 to T1n is increased due to the application of voltage, the temperature of supplied electrolytic solution L may be controlled to cool the electrolytic solution L in the inner baths T11 to T1n.

As in the third embodiment, the electrolytic solution L in the inner baths T11 to T1n may be circulated. With the semiconductor manufacturing tool 100 according to the third embodiment, it is possible to produce similar effects as in the first embodiment. Furthermore, the semiconductor manufacturing tool 100 according to the third embodiment may be combined with the second embodiment.

### Fourth Embodiment

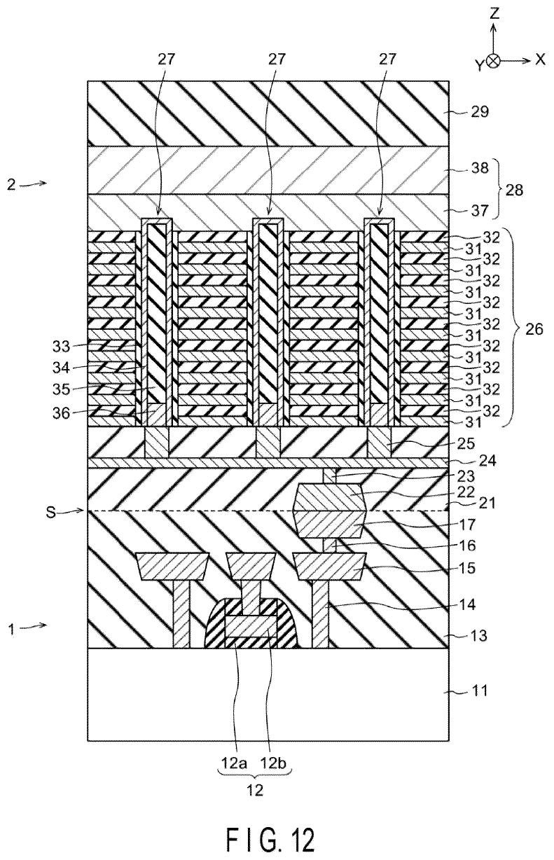

FIG. 12 is a sectional view illustrating the structure of a semiconductor device of the fourth embodiment. The semiconductor device in FIG. 12 is, for example, a three-dimensional flash memory.

The semiconductor device in FIG. 12 includes a circuit region 1 that includes a complementary metal oxide semiconductor (CMOS) circuit and an array region 2 that includes a memory cell array. The memory cell array includes a plurality of memory cells that store data, and the CMOS circuit includes a peripheral circuit that controls the operation of the memory cell array. The semiconductor device in FIG. 12 is, for example, produced by bonding a circuit wafer that includes the circuit region 1 and an array wafer that includes the array region 2, as described later. A reference sign S indicates a bonding interface between the circuit region 1 and the array region 2.

In FIG. 12, the circuit region 1 includes a substrate 11, a transistor 12, an interlayer dielectric 13, a plurality of contact plugs 14, a wiring layer 15 that includes a plurality of wirings, a via plug 16, and a metal pad 17. FIG. 12 illustrates three wirings of the plurality of wirings in the wiring layer 15 and three contact plugs 14 provided under the wirings. The substrate 11 is an example of the second substrate.

In FIG. 12, the array region 2 includes an interlayer dielectric 21, a metal pad 22, a via plug 23, a wiring layer 24 that includes a plurality of wirings, a plurality of contact plugs 25, a stacked film 26, a plurality of columnar portions 27, a source layer 28, and an insulation film 29. FIG. 12 illustrates one wiring of the plurality of wirings in the wiring layer 24 and three contact plugs 25 and three columnar portions 27 provided above the wiring.

Furthermore, as illustrated in FIG. 12, the stacked film 26 includes a plurality of electrode layers 31 and a plurality of insulation layers 32. The columnar portions 27 each include a memory insulation film 33, a channel semiconductor layer 34, a core insulation film 35, and a core semiconductor layer 36. The source layer 28 includes a semiconductor layer 37 and a metal layer 38.

The structure of the semiconductor device of the embodiment will now be described with reference to FIG. 12.

The substrate 11 is, for example, a semiconductor substrate such as an Si substrate. The transistor 12 includes a gate insulation film 12a and a gate electrode 12b formed on the substrate 11 in this order and a source diffusion layer and a drain diffusion layer, which are not illustrated, formed in the substrate 11. The transistor 12 constitutes a CMOS circuit described above, for example. The interlayer dielectric 13 is formed on the substrate 11 to cover the transistor 12. The interlayer dielectric 13 is, for example, an SiO₂ film (silicon oxide film) or a stacked film that includes an SiO₂ film and other insulation films.

The contact plugs 14, the wiring layer 15, the via plug 16, and the metal pad 17 are formed in the interlayer dielectric 13. Specifically, a contact plug 14 is disposed on the substrate 11, or on the gate electrode 12b of the transistor 12. In FIG. 12, contact plugs 14 on the substrate 11 are provided on a source diffusion layer and a drain diffusion layer, which are not illustrated, of the transistor 12. The wiring layer 15 is disposed on the contact plug 14 and the via plug 16 is disposed on the wiring layer 15. The metal pad 17 is disposed on the via plug 16 above the substrate 11. The metal pad 17 is, for example, a metal layer that includes a Cu (copper) layer.

The interlayer dielectric 21 is formed on the interlayer dielectric 13. The interlayer dielectric 21 is, for example, an SiO₂ film or a stacked film that includes an SiO₂ film and other insulation films.

The metal pad 22, the via plug 23, the wiring layer 24, and the contact plugs 25 are formed in the interlayer dielectric 21. Specifically, the metal pad 22 is disposed on the metal pad 17 above the substrate 11. The metal pad 22 is, for example, a metal layer that includes a Cu layer. The via plug 23 is disposed on the metal pad 22, and the wiring layer 24 is disposed on the via plug 23. FIG. 12 illustrates one wiring of the plurality of wirings in the wiring layer 24, and the wiring functions, for example, as a bit line. The contact plugs 25 are disposed on the wiring layer 24.

The stacked film 26 is provided on the interlayer dielectric 21 and includes a plurality of electrode layers 31 and a plurality of insulation layers 32, which are alternately stacked in the Z-direction. The electrode layer 31 is, for example, a metal layer that includes a W (tungsten) layer and functions as a word line. The insulation layer 32 is, for example, an SiO₂ film.

The columnar portions 27 are each provided in the stacked film 26 and include the memory insulation film 33, the channel semiconductor layer 34, the core insulation film 35, and the core semiconductor layer 36. The memory insulation film 33 is formed on a side surface of the stacked film 26 and has a tubular shape extending in the Z-direction. The channel semiconductor layer 34 is formed on a side surface of the memory insulation film 33 and has a tubular shape extending in the Z-direction. The core insulation film 35 and the core semiconductor layer 36 are formed on a side surface of the channel semiconductor layer 34 and each have a bar shape extending in the Z-direction. Specifically, the core semiconductor layer 36 is disposed on the contact plug 25, and the core insulation film 35 is disposed on the core semiconductor layer 36.

The memory insulation film 33 includes, for example, a block insulation film, a charge storage layer, and a tunnel insulation film in this order, as described later. The block insulation film is, for example, an SiO₂ film. The charge storage layer is, for example, an SiN film (silicon nitride film). The tunnel insulation film is, for example, an SiO₂ film or an SiON film (silicon oxynitride film). The channel semiconductor layer 34 is, for example, a polysilicon layer. The core insulation film 35 is, for example, an SiO₂ film. The core semiconductor layer 36 is, for example, a polysilicon layer. Each memory cell in the memory cell array described above is constituted of the channel semiconductor layer 34, the charge storage layer, the electrode layer 31, and the like.

The channel semiconductor layer 34 and the core semiconductor layer 36 in each of the columnar portions 27 are electrically connected to the metal pad 22 via the contact plug 25, the wiring layer 24, and the via plug 23. Accordingly, the memory cell array in the array region 2 is electrically connected to a peripheral circuit in the circuit region 1 via the metal pad 22 or the metal pad 17. This makes it possible to control the operation of the memory cell array by the peripheral circuit.

The source layer 28 includes the semiconductor layer 37 and the metal layer 38 formed in this order on the stacked film 26 and the columnar portion 27, and functions as a source line. In the embodiment, the channel semiconductor layer 34 of each of the columnar portions 27 is exposed from the memory insulation film 33, and the semiconductor layer 37 is formed directly on the channel semiconductor layer 34. Furthermore, the metal layer 38 is formed directly on the semiconductor layer 37. Accordingly, the source layer 28 is electrically connected to the channel semiconductor layer 34 and the core semiconductor layer 36 of each of the columnar portions 27. The semiconductor layer 37 is, for example, a polysilicon layer. The metal layer 38 includes, for example, a W layer, a Cu layer, or an Al (aluminum) layer.

The insulation film 29 is formed on the source layer 28. The insulation film 29 is, for example, an SiO₂ film.

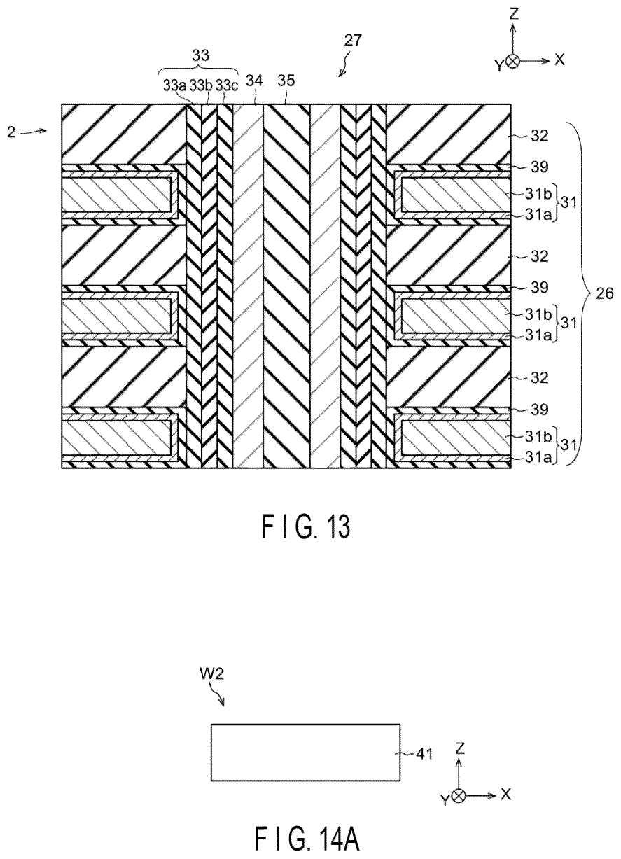

FIG. 13 is an enlarged sectional view illustrating the structure of the semiconductor device of the fourth embodiment.

FIG. 13 illustrates three electrode layers 31 and three insulation layers 32, which are included in the stacked film 26, and one columnar portion 27 provided in the stacked film 26. As described above, the memory insulation film 33 in the columnar portion 27 includes a block insulation film 33a, a charge storage layer 33b, and a tunnel insulation film 33c, which are formed in this order on a side surface of the stacked film 26. The block insulation film 33a is, for example, an SiO₂ film. The charge storage layer 33b is, for example, an SiN film. The tunnel insulation film 33c is, for example, an SiO₂ film or an SiON film.

Meanwhile, each of the electrode layers 31 includes a barrier metal layer 31a and an electrode material layer 31b. The barrier metal layer 31a is, for example, a TiN film (titanium nitride film). The electrode material layer 31b is, for example, a W layer. As illustrated in FIG. 13, each of the electrode layers 31 of the embodiment is formed on the lower surface of an insulation layer 32 located above, the upper surface of an insulation layer 32 located below, and a side surface of the block insulation film 33a via the block insulation film 39. The block insulation film 39 is, for example, an Al₂O₃ film (aluminum oxide film) and functions as a block insulation film of each memory cell along with the block insulation film 33a.

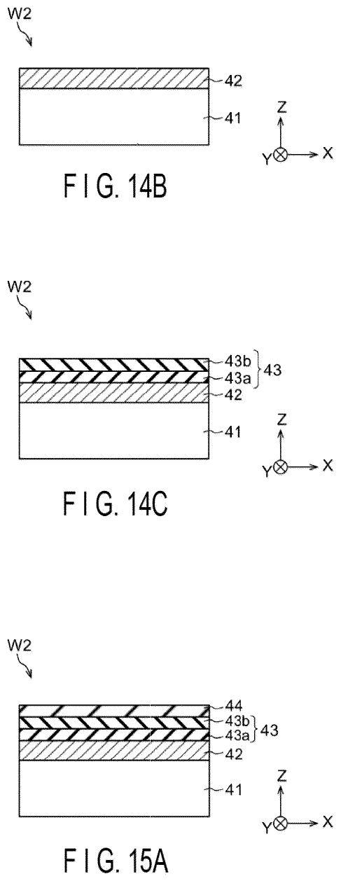

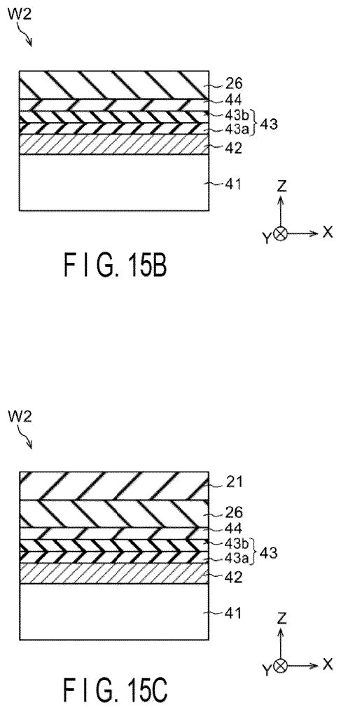

FIGS. 14A to 14C and FIGS. 15A to 15C are sectional views illustrating a manufacturing method of the semiconductor device of the fourth embodiment. The semiconductor device of the embodiment is produced by bonding a circuit wafer W1 described later and an array wafer W2. The circuit wafer W1 is used to produce the circuit region 1 and the array wafer W2 is used to produce the array region 2. The circuit wafer W1 and the array wafer W2 each have a disc shape.

First, a substrate 41 for the array wafer W2 is provided (FIG. 14A). The substrate 41 is, for example, a semiconductor substrate such as an Si substrate. The substrate 41 corresponds to the substrate W of the first embodiment. The substrate 41 is an example of the first substrate.

Next, a porous layer 42 is formed on the substrate 41 (FIG. 14B). The porous layer 42 is, for example, a porous semiconductor layer such as a porous polysilicon layer. For example, the porous layer 42 is formed by forming a material layer for forming the porous layer 42 on the substrate 41 and forming pores in the material layer. That is, the porous layer 42 is formed by generating porosity in the material layer. In a case in which the material layer is a polysilicon layer (more generally, a semiconductor layer), the porous layer 42 is a porous polysilicon layer (more generally, a porous semiconductor layer). The porosity in the material layer is generated, for example, by setting the substrate 41 on which the material layer is formed in the substrate processor 101 described above and applying the anodization to the material layer. Consequently, the material layer is transformed to the porous layer 42 by anodization. The material layer is an example of the first layer. Note that the porous layer 42 may be formed in the substrate 41, or may be formed on the substrate 41 via any other layer.

Next, a cap insulation film 43 is formed on the porous layer 42 (FIG. 14C). The cap insulation film 43 includes an insulation film 43a formed on the porous layer 42 and an insulation film 43b formed on the insulation film 43a. The insulation film 43a is, for example, an SiO₂ film. The insulation film 43b is, for example, an SiN film.

Next, an insulation film 44 is formed on the cap insulation film 43 (FIG. 15A). The insulation film 44 is, for example, an SiO₂ film.

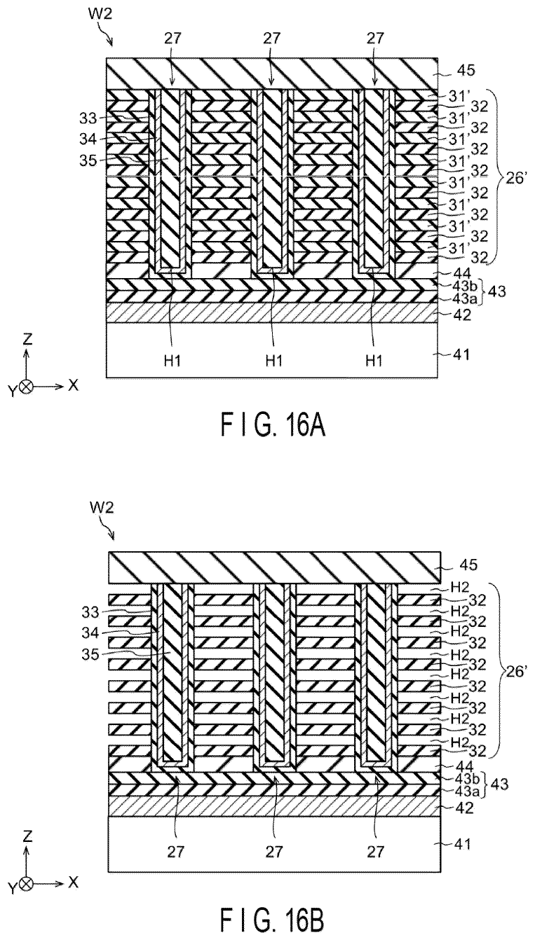

Next, a stacked film 26 and an interlayer dielectric 21 are formed on the insulation film 44 in this order (FIGS. 15B and 15C). The stacked film 26 and the interlayer dielectric 21 have been described above in detail with reference to FIG. 12. FIGS. 15B and 15C schematically illustrate the structures of the stacked film 26 and the interlayer dielectric 21. The processes illustrated in FIGS. 15B and 15C and subsequent processes will be described later with reference to FIGS. 16A to 20B.

FIGS. 16A to 20B are sectional views illustrating details of the manufacturing method of the semiconductor device of the fourth embodiment.

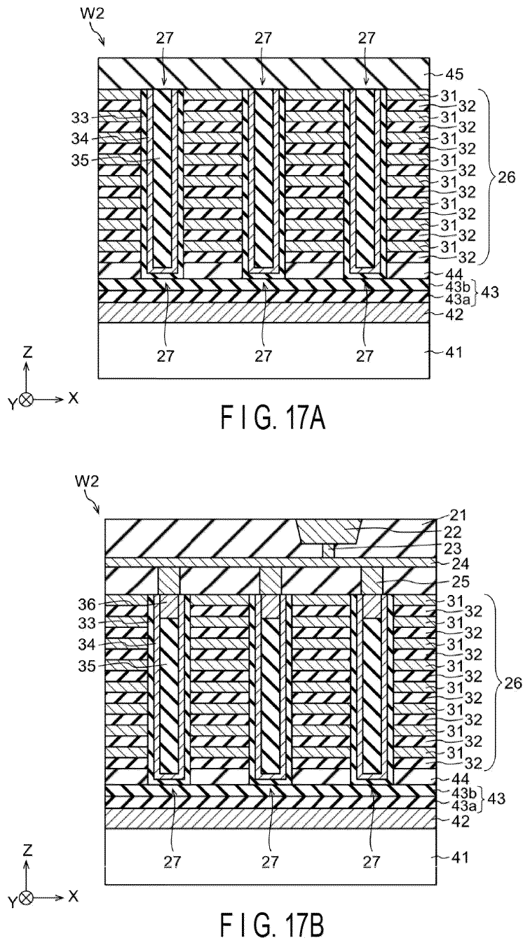

FIGS. 16A to 17B illustrate the processes illustrated in FIGS. 15B and 15C in detail. First, the insulation film 44 is formed on the cap insulation film 43 and a stacked film 26′ is formed on the insulation film 44 (FIG. 16A). The stacked film 26′ is a film for forming the stacked film 26 through a replacing process. The stacked film 26′ is formed such that a plurality of sacrificial layers 31′ and a plurality of insulation layers 32 are included in an alternate manner. The sacrificial layer 31′ is, for example, an SiN film.

Next, a plurality of memory holes H1 passing through the stacked film 26′ and the insulation film 44 are formed, and a memory insulation film 33, a channel semiconductor layer 34, and a core insulation film 35 are formed in each memory hole H1 in this order (FIG. 16A). As a result, a plurality of columnar portions 27 that extend in the Z-direction are formed in the memory holes H1. The memory insulation film 33 is formed by forming a block insulation film 33a, a charge storage layer 33b, and tunnel insulation film 33c in each memory hole H1 in this order (see FIG. 13).

Next, the insulation film 45 is formed on the stacked film 26′ and the columnar portion 27 (FIG. 16A). The insulation film 45 is, for example, an SiO₂ film.

Next, a slit (not illustrated) passing through the insulation film 45 and the stacked film 26′ is formed and the sacrificial layer 31′ is removed through wet etching by using the slit (FIG. 16B). As a result, a plurality of cavities H2 are formed in the stacked film 26′ between the insulation layers 32.

Next, a plurality of electrode layers 31 are formed in the cavities H2 from the slit (FIG. 17A). As a result, the stacked film 26 that alternately includes a plurality of electrode layers 31 and a plurality of insulation layers 32 is formed between the insulation film 44 and the insulation film 45). Furthermore, a structure of the plurality of columnar portions 27 described above passing through the stacked film 26 is formed above the substrate 41. Note that when the electrode layer 31 is formed in each cavity H2, the block insulation film 39, the barrier metal layer 31a, and the electrode material layer 31b are formed in each cavity H2 in this order (see FIG. 13).

Next, the insulation film 45 is removed, a part of the core insulation film 35 in each columnar portion 27 is removed, and a core semiconductor layer 36 is embedded in a region in which the part of the core insulation film 35 is removed (FIG. 17B). As a result, each columnar portion 27 is processed into a structure that includes the memory insulation film 33, the channel semiconductor layer 34, the core insulation film 35, and the core semiconductor layer 36.

Next, the interlayer dielectric 21, the metal pad 22, the via plug 23, the wiring layer 24, and the plurality of contact plugs 25 are formed on the stacked film 26 and the columnar portion 27 (FIG. 17B). At this time, the contact plugs 25 are each formed on the core semiconductor layer 36 of the corresponding columnar portion 27, and the wiring layer 24, the via plug 23, and the metal pad 22 are formed on the contact plugs 25 in this order. Note that FIG. 17B illustrates a state that is the same as the state illustrated in FIG. 15C.

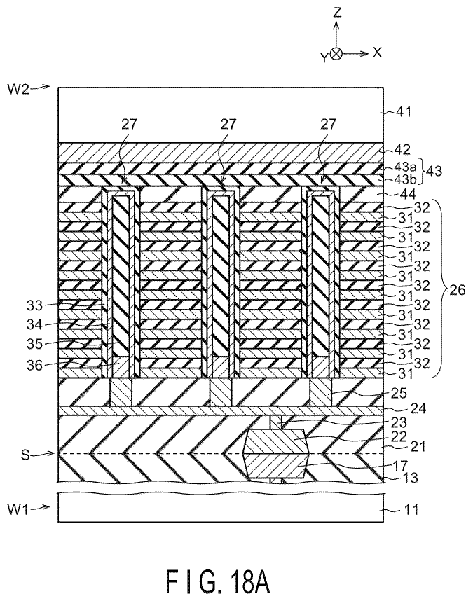

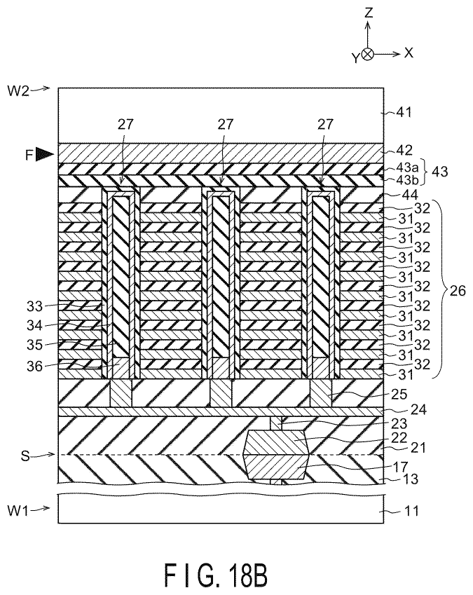

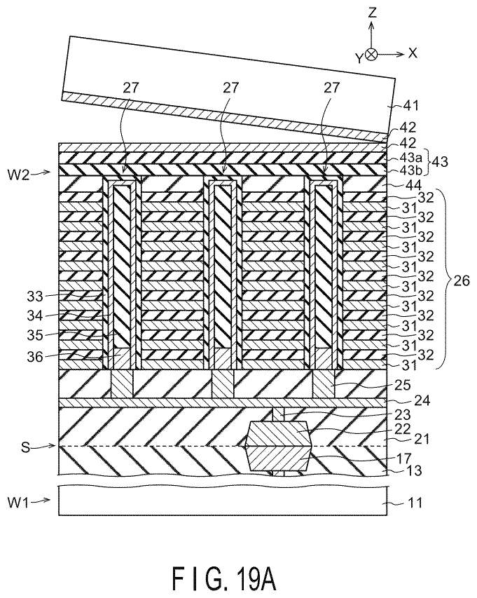

FIG. 18A illustrates a process of bonding the circuit wafer W1 and the array wafer W2. The circuit wafer W1 illustrated in FIG. 18A is produced by providing the substrate 11 and forming the transistor 12, the interlayer dielectric 13, the plurality of contact plugs 14, the wiring layer 15, the via plug 16, and the metal pad 17 on the substrate 11 (see FIG. 12). At this time, the transistor 12 is formed on the substrate 11 and the contact plugs 14 are formed on the substrate 11 or the transistor 12. Furthermore, the wiring layer 15, the via plug 16, the metal pad 17 are formed on the contact plugs 14 in this order.

Next, the array wafer W2 is flipped upside down, and the circuit wafer W1 and the array wafer W2 are bonded under a mechanical pressure (FIG. 18A). As a result, the interlayer dielectric 13 and the interlayer dielectric 21 are adhered. Next, the circuit wafer W1 and the array wafer W2 are annealed (FIG. 18A). As a result, the metal pad 17 and the metal pad 22 are joined. In this way, the substrate 11 and the substrate 41 are bonded while the interlayer dielectrics 13 and 21, the stacked film 26, the insulation film 44, the cap insulation film 43, and the porous layer 42 are located in between, so that the substrate 41 is stacked above the substrate 11. Each metal pad 22 is disposed on the corresponding metal pad 17.

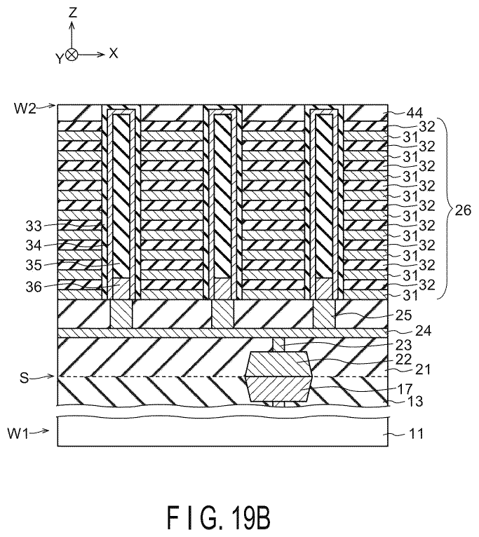

Next, a physical force F is applied to the array wafer W2 by using a blade or a water jet (FIG. 18B). For example, a force F is applied to the section of the porous layer 42. As a result, the porous layer 42 is torn off. In this way, the substrate 11 and the substrate 41 are separated from each other (FIG. 19A). In FIGS. 18B and 19A, the force F is applied to the section of the porous layer 42, and the porous layer 42 is torn off, so that the substrate 11 and the substrate 41 are separated at a position of the porous layer 42 from each other. As a result, a part of the porous layer 42 remains on a surface of substrate 41, and the remainder of the porous layer 42 remains on a surface on the side of the substrate 11. Furthermore, the memory cell array and the CMOS circuit described above also remain on a surface of the substrate 11. The porous layer 42 is divided into a portion on the side of the substrate 41 and a portion on the side of the substrate 11. The former portion is an example of a first portion, and the latter portion is an example of a second portion. The porous layer 42 functions as a separation layer (detachment layer) for separating (detaching) the substrate 41 from the substrate 11.

The porous layer 42 of the embodiment is breakable because it includes a large number of voids. Accordingly, the porous layer 42 can be torn off by applying the force F to the porous layer 42. Note that instead of the porous layer 42, or in addition to the porous layer 42, any other material than the porous layer 42 (for example, cap insulation film 43) may be torn off to separate the substrate 11 from the substrate 41. In this case, the force F may be applied to the material.

In the embodiment, instead of grinding the substrate 41, the substrate 41 above the substrate 11 is removed by detaching the substrate 41 from the substrate 11. In this way, it is possible to prevent the substrate 41 from being damaged, which makes it possible to reuse the substrate 41. In the embodiment, after the substrate 11 and the substrate 41 are separated from each other, the porous layer 42 or the like remaining on the surface of the substrate 41 is removed to reuse the substrate 41 in the bonding process illustrated in FIG. 18A. In this way, it is possible to avoid wastefully using a large number of substrates 41. Note that the force F may be applied to the porous layer 42 mechanically such as using a blade, fluidly such as using a water jet, or otherwise in any other manner.

Next, the porous layer 42 and the cap insulation film 43 above the substrate 11 are removed (FIG. 19B). As a result, the insulation film 44 and the columnar portions 27 are exposed above the substrate 11. The process illustrated in FIG. 19B is achieved, for example, through CMP (Chemical Mechanical Polishing) or etching. In the process in FIG. 19B, the substrate 11 may be thinned through CMP or etching.

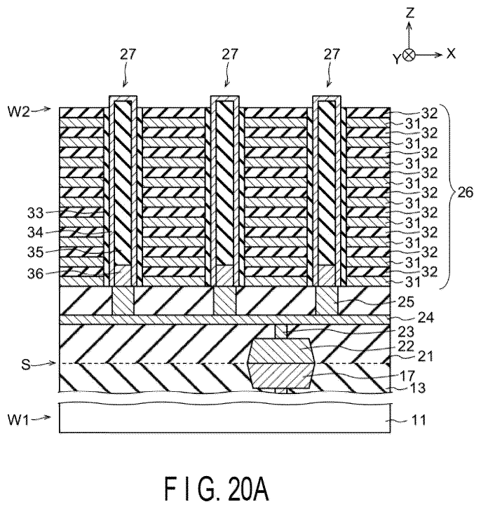

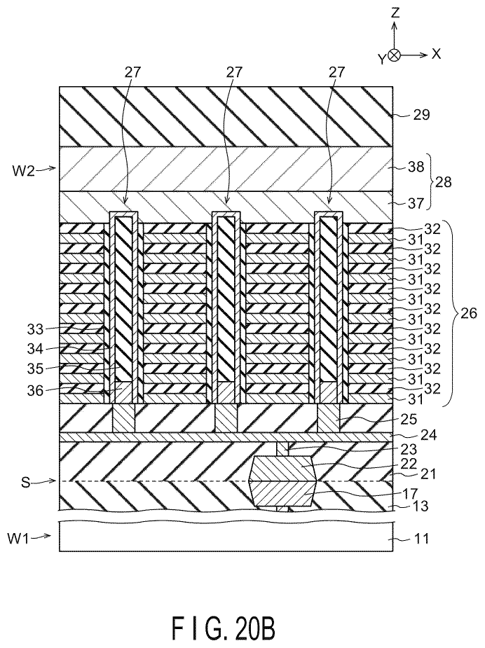

Next, the insulation film 44 and a part of the memory insulation film 33 of each columnar portion 27 are etched away (FIG. 20A). The portion to be removed in the memory insulation film 33 is, for example, a portion exposed from the stacked film 26. As a result, a part of the channel semiconductor layer 34 of each columnar portion 27 is exposed from the memory insulation film 33 at a position higher than the stacked film 26.

Next, the semiconductor layer 37, the metal layer 38, and the insulation film 29 are formed on the stacked film 26 and the columnar portion 27 in this order (FIG. 20B). As a result, the source layer 28 is formed on the channel semiconductor layer 34 of each columnar portion 27 and electrically connected to the channel semiconductor layer 34 of each columnar portion 27.

Thereafter, the circuit wafer W1 and the array wafer W2 are cut into a plurality of chips. The chips are cut out such that each chip includes the circuit region 1 and the array region 2. In this way, the semiconductor device in FIG. 12 is produced.

The semiconductor device of the embodiment may be put on the market in a state illustrated in FIG. 12 or may be put on the market in a state illustrated in FIG. 17B or FIG. 18A.

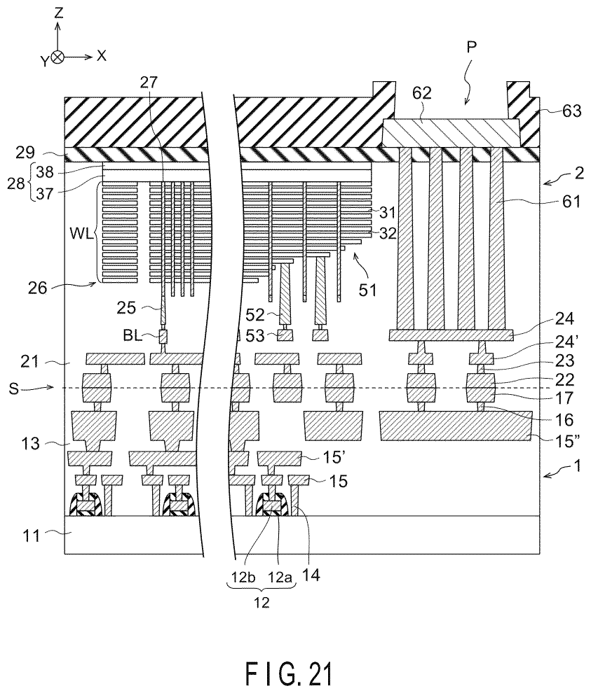

FIG. 21 is a sectional view illustrating the structure of a semiconductor device of a modification of the fourth embodiment. Instead of having the structure illustrated in FIG. 12, the semiconductor device described with reference to FIGS. 12 to 20B may have the structure illustrated in FIG. 21.

As in the semiconductor device of the fourth embodiment, the semiconductor device of the modification includes the circuit region 1 and the array region 2. In addition to the components illustrated in FIG. 12, the circuit region 1 includes wiring layers 15′ and 15″ that electrically connect the wiring layer 15 and the via plug 16. In addition to the components illustrated in FIG. 12, the array region 2 includes a wiring layer 24′ that electrically connects the via plug 23 and the wiring layer 24. Each of the wiring layers 15′, 15″, and 24′ includes a plurality of wirings as in the wiring layer 15 and the wiring layer 24.

FIG. 21 illustrates a plurality of word lines WL (depicted as electrode layers 31) in the stacked film 26, a plurality of columnar portions 27 passing through the stacked film 26, and a stepped structured portion 51 of the stacked film 26. Each word line WL is electrically connected to the word wiring layer 53 at the stepped structured portion 51 via the contact plug 52. Each columnar portion 27 is electrically connected to the bit line BL via the contact plug 25 and electrically connected to the source layer 28. The word wiring layer 53 and the bit line BL of the modification are included in the wiring layer 24.

The array region 2 further includes a plurality of via plugs 61 provided on the wiring layer 24, a metal pad 62 provided on the via plugs 61 or the insulation film 29, and a passivation film 63 provided on the metal pad 62 or the insulation film 29. The passivation film 63, which is, for example, a stacked insulation film that includes silicon oxide film, silicon nitride film, or the like, has an opening P in which the upper surface of the metal pad 62 is exposed. The metal pad 62 is an external connecting pad of the semiconductor device of the modification and is connectable to a mounting substrate or any other device via a solder ball, a metal bump, a bonding wire, or the like.

As described above, the semiconductor device of the embodiment is produced by using the porous layer 42 formed by the substrate processor 101 of the first embodiment. According to the embodiment, therefore, the porous layer 42 can suitably be formed on a surface of the substrate 41. Furthermore, according to the embodiment, it is possible to reuse the substrate 41 by detaching the substrate 41 from the substrate 11.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor manufacturing tool, comprising:
a plurality of process baths, each of which is capable of containing a substrate processing liquid and accommodating a first substrate;
a plurality of anodes and a plurality of cathodes, wherein one of the anodes and one of the cathodes are provided for each of the process baths; and
an electrical circuit configured to electrically connect a plurality of first substrates accommodated in the process baths and in the substrate processing liquid, via the anodes and the cathodes, and supplies electrical power via the anodes and the cathodes to subject the first substrates to an electrochemical process.

2. The semiconductor manufacturing tool of claim 1, wherein the electrochemical process is an anodization process.

3. The semiconductor manufacturing tool of claim 1, further comprising a substrate holder capable of each of the first substrates to one of the anodes.

4. The semiconductor manufacturing tool of claim 3, wherein the substrate holder is configured to hold the first substrates while exposing a first surface of the first substrates to the substrate processing liquid.

5. The semiconductor manufacturing tool of claim 3, wherein the substrate holder is capable of securing the plurality of the first substrates respectively to the plurality of anodes.

6. The semiconductor manufacturing tool of claim 5, further comprising an electrode holder configured to hold the plurality of anodes such that the plurality of anodes can be brought into and out of the substrate processing liquid in the process baths.

7. The semiconductor manufacturing tool of claim 1, wherein the anodes are made of at least one of a base metal that is less susceptible to oxidation than a material of the first substrate, a compound semiconductor that is less susceptible to oxidation than a material of the first substrate, carbon, a conductive polymer, and a noble metal.

8. The semiconductor manufacturing tool of claim 1, further comprising a covering film that covers at least a partial region of the anodes, the covering film having an electrical conductivity and being made of a material that is different from a material of the anodes.

9. The semiconductor manufacturing tool of claim 8, wherein the covering film is made of a conductive polymer.

10. The semiconductor manufacturing tool of claim 1, wherein the electrical circuit connects the plurality of first substrates in series via the anodes and the cathodes.

11. The semiconductor manufacturing tool of claim 10, further comprising:
a power supply circuit configured to control a current flowing through the electrical circuit.

12. The semiconductor manufacturing tool of claim 1, wherein the electrical circuit connects a plurality of first substrates in parallel via the anodes and the cathodes.

13. The semiconductor manufacturing tool of claim 10, further comprising:
a power supply circuit configured to control a voltage applied to the first substrates.

14. The semiconductor manufacturing tool of claim 1, wherein each of the process baths includes a liquid supply part by which new substrate processing liquid is supplied into the process baths and a liquid drain part by which used substrate processing liquid is discharged from the process baths.

15. A method of batch processing a plurality of semiconductor wafers in a semiconductor manufacturing tool that includes a plurality of process baths, each of which is capable of containing a processing liquid, said method comprising:
placing a plurality of first electrodes respectively in the processing baths;
securing a plurality of semiconductor wafers respectively to a plurality of second electrodes provided on a substrate holder;
moving the substrate holder to place the plurality of semiconductor wafers and the plurality of second electrodes respectively in the process baths;
supplying electrical power via the first electrodes and the second electrodes to subject the semiconductor wafers to an electrochemical process.

16. The method according to claim 15, wherein the electrochemical process is an anodization process.

17. The method according to claim 15, wherein the semiconductor wafers are electrically connected in series via the first electrodes and the second electrodes.

18. The method according to claim 17, further comprising:
controlling a current flowing through the semiconductor wafers via the first electrodes and the second electrodes.

19. The method according to claim 15, wherein the semiconductor wafers are electrically connected in parallel via the first electrodes and the second electrodes.

20. The method according to claim 19, further comprising:
controlling a voltage applied to the semiconductor wafers via the first electrodes and the second electrodes.
